(19) United States
(12) Patent Application Publication
(10) Pub. No.: US 2012/0087099 A1
(43) Pub. Date: Apr. 12, 2012

(54) Printed Circuit Board For Board-On-Chip Package, Board-On-Chip Package Including The Same, And Method Of Fabricating The Board-On-Chip Package

(75) Inventors: Taeho Moon, Cheonan-si (KR); Whasu Sin, Cheonan-si (KR); Junsoo Han, Cheonan-si (KR); Jee-Min Park, Asan-si (KR)

(73) Assignee: SAMSUNG ELECTRONICS CO., LTD., Suwon-si (KR)

(21) Appl. No.: 13/195,289

(22) Filed: Aug. 1, 2011

(30) Foreign Application Priority Data
Oct. 8, 2010 (KR) 10-2010-0098118

(51) Int. Cl. H05K 7/02

(52) U.S. Cl. 361/783

(57) ABSTRACT

Provided is a printed circuit board for a board-on-chip package prepared with a strip level of a plurality of unit substrates and including a reject marking portion for determining whether there is a defective unit substrate, wherein the reject marking portion is in each unit substrate.

### CROSS-REFERENCE TO RELATED APPLICATIONS

This U.S. non-provisional patent application claims priority under 35 U.S.C. §119 to Korean Patent Application No. 10-2010-0098118, filed on Oct. 8, 2010, in the Korean Intellectual Property Office (KIPO), the entire contents of which are hereby incorporated by reference.

### BACKGROUND

1. Field

Example embodiments relate to a printed circuit board for a board-on-chip package, a board-on-chip package including the same, and a method of fabricating the board-on-chip package.

2. Description of the Related Art

Recent electronic equipment becomes more miniaturized than before and for this, a more miniaturized and high performance semiconductor chip package is required. According to this trend, a semiconductor chip package mainly includes a multi chip package having a plurality of semiconductor chips stacked vertically or arranged in a plane in a package or a board-on-chip package having a semiconductor attached directly to a substrate and sealing it to reduce a package size. Unlike a typical method in which a semiconductor is mounted on a substrate through a lead frame, a Board on Chip (BoC) receives great attention as a substrate for the next generation high speed semiconductor, which is used for a high speed Dynamic Random Access Memory (DRAM) of a Digital Disk Recorder (DDR) 2, because a semiconductor chip itself is directly mounted on a substrate thereby minimizing thermal and electrical performance losses due to a high-speed DRAM. A capacity of a current DRAM has drastically increased, for example, the capacity has increased from 128 MB, 256 MB, 512 MB, 1 GB, and 2 GB and in order to meet this trend, electrical loss needs to be minimized or reduced and also, the reliability of a product needs to be improved or maintained.

### SUMMARY

Example embodiments provide a printed circuit board for a board-on-chip package for preventing or reducing recognition errors of a reject mark. Example embodiments also provide a board-on-chip package with a reliable reject mark. Example embodiments also provide a method of fabricating a board-on-chip package for preventing or reducing recognition errors of a reject mark.

Example embodiments provide printed circuit boards for a board-on-chip package. The printed circuit boards may be prepared with a strip level and the printed circuit boards may include a plurality of unit substrates. In example embodiments, the unit substrates may include a reject marking portion for determining whether the unit substrate is defective. In example embodiments, the reject marking portion may be disposed in each unit substrate.

In example embodiments, the unit substrate may include a circuit region and a peripheral region at an edge of the circuit region, and the reject marking portion may be disposed in the peripheral region.

In example embodiments, the unit substrate may include a circuit pattern and a plated lead-in line connected to the circuit pattern, and the reject marking portion may be connected to the plated lead-in line.

In example embodiments, the reject marking portion may have a circular, polygonal, or cross shape.

In example embodiments, the unit substrate may have a first side to which a solder ball is attached and a second side on which a semiconductor chip is mounted, and the reject marking portion may be disposed on the first side.

In example embodiments, the unit substrate may include an opening region, and the reject marking portion may be disposed adjacent to the opening region.

In example embodiments, board-on-chip packages may include a unit substrate and the unit substrate may include a reject marking portion and an opening. In example embodiments a semiconductor chip may be mounted on one side of the unit substrate and the semiconductor chip may be electrically connected to the unit substrate through the opening.

In example embodiments, a method of fabricating a board-on-chip package may include preparing a strip-level base substrate having a first side and a second side facing the first side and including a plurality of unit substrates, forming a circuit pattern, a plated lead-in line, and a reject marking portion on the first side in each unit substrate, forming a first insulation layer on the first side to expose the circuit pattern, a portion of the plated lead-in line, and the reject marking portion and forming a second insulation layer on the second side, and forming a plated layer on a portion of the exposed circuit pattern and the reject marking portion by applying electricity to the exposed portion of the plated lead-in line.

In example embodiments, the method may further include forming an opening by removing a portion of the plated lead-in line and the base substrate therebelow in each unit substrate, and fanning a reject mark on a reject marking portion of a corresponding defective unit substrate after the each unit substrate is tested.

In example embodiments, the methods may further include mounting a semiconductor chip on the second side in each unit substrate and electrically connecting the semiconductor chip with the circuit pattern through the opening.

### BRIEF DESCRIPTION OF THE DRAWINGS

The accompanying drawings are included to provide a further understanding of example embodiments, and are incorporated in and constitute a part of this specification. The drawings illustrate example embodiments and, together with the description, serve to explain principles of example embodiments. In the drawings:

FIG. 1 is a plan view illustrating a strip-level substrate for a board-on-chip package according to example embodiments;

FIG. 2A is a plan view of a unit substrate in a portion A of FIG. 1;

FIGS. 2B and 2C are sectional views taken along the line I-I′ and the line II-II′ of FIG. 2A, respectively;

FIG. 3A is a plan view illustrating a reject mark on the unit substrate of FIG. 2A;

FIG. 3B is a sectional view taken along the line II-IF of FIG. 3A;

FIGS. 4A and 5A are plan views illustrating processes of fabricating the unit substrate of FIG. 2A;

FIGS. 4B and 5B are sectional views taken along the lines I-I′ of FIGS. 4A and 5A, respectively;

FIGS. 4C and 5C are sectional views taken along the lines II-II′ of FIGS. 4A and 5A, respectively;

FIGS. 6A, 7A, and 8A are plan views sequentially illustrating processes of forming a board-on-chip package according to example embodiments;

FIGS. 6B, 7B, and 8B are sectional views taken along the lines I-I′ of FIGS. 6A, 7A, and 8A;

FIGS. 6C, 7C, and 8C are sectional views taken along the lines II-II′ of FIGS. 6A, 7A, and 8A;

FIGS. 9 and 10 are plan views illustrating strip-level substrates for a board-on-chip package according to example embodiments;

FIG. 11 is a view illustrating an example of a package module including a semiconductor package that the technique of example embodiments is applied;

FIG. 12 is a block diagram illustrating an example of an electronic device including a semiconductor package that the technique of example embodiments is applied; and

FIG. 13 is a block diagram illustrating a memory system with a semiconductor package that the technique of example embodiments is applied.

### DETAILED DESCRIPTION OF THE EMBODIMENTS

Example embodiments will be described more fully hereinafter with reference to the accompanying drawings, in which example embodiments are shown. The present invention may, however, be embodied in many different forms and should not be construed as limited to example embodiments as set forth herein. Rather, example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers that may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the present invention. As used herein, the singular forms “a,” “an” and “the” are intended to include the plural forms as well, unless the context clearly indicates otherwise. It will be further understood that the teens “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

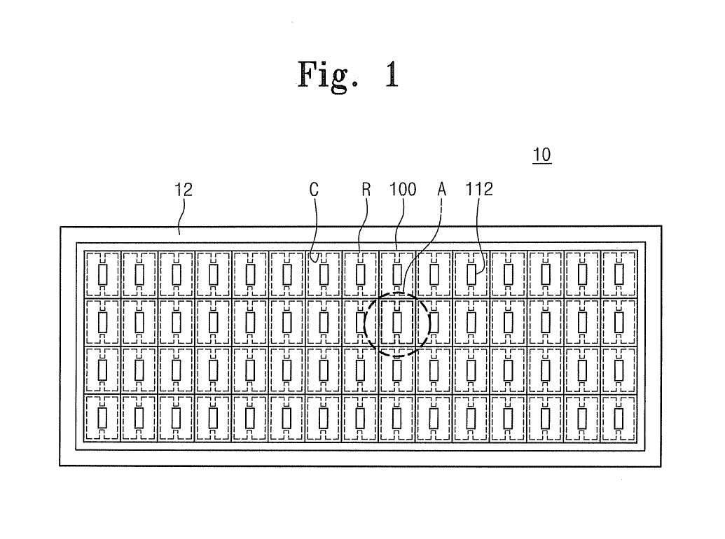

FIG. 1 is a plan view illustrating a strip-level substrate for a board-on-chip package according to example embodiments.

Referring to FIG. 1, a printed circuit board 10 of a strip-level substrate for a board-on-chip package may include a plurality of unit substrates 100. Each of the unit substrates 100 may include a circuit region C and a peripheral region R, where an opening 112 is disposed in the center of the circuit region C. In the printed circuit board 10 of the strip-level, a reject marking portion for determining whether there is a defective unit substrate 100 is not provided at a frame 12, which is an edge of the unit substrate 100. In the unit substrates 100 for a board-on-chip package, a reject marking portion is provided in each of the unit substrates 100. This will be described in more detail.

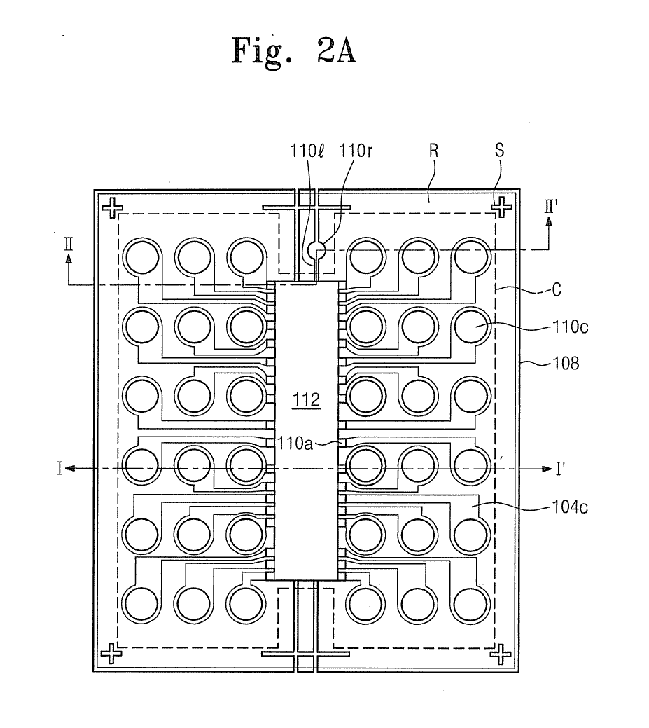

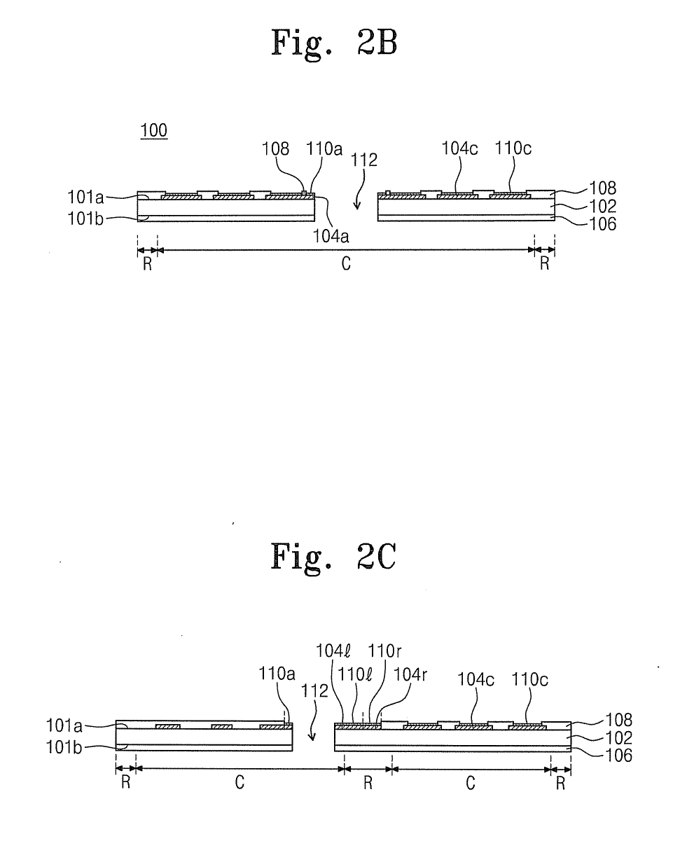

FIG. 2A is a plan view of a unit substrate in a portion A of FIG. 1. FIGS. 2B and 2C are sectional views taken along the line I-I′ and the line II-II′ of FIG. 2A, respectively.

Referring to FIGS. 2A through 2C, the unit substrate 100 for a board-on-chip package may include a base substrate 102 having a circuit region C and a peripheral region R corresponding to a peripheral of the circuit region C. The base substrate 102 may include insulation material. The base substrate 102 includes a first side 101a and a second side 101b facing thereto. Circuit patterns 104c may be disposed in the circuit region C on the first side 101a. A reject marking portion 104r may be disposed in the peripheral region R on the first side 101a. An alignment mark S may be disposed at the edge of the peripheral region R. A plated lead-in line 1041 may be disposed on the first side 101a, crossing over the circuit region C and the peripheral region R. The plated lead-in line 1041 may be connected to the reject marking portion 104r. The base substrate at the center of the circuit region C may include openings 112. A pad unit 104a may be disposed on the first side 101a adjacent to the opening 112. The reject marking portion 104r may be disposed in the peripheral region R adjacent to the opening 112 and may be connected to the plated lead-in line 1041. A first insulation layer 108 may be disposed on the first side 101a to cover a portion of the circuit patterns 104c but expose a portion of the circuit patterns 104c, the pad unit 104a, the reject marking portion 104r, and the plated lead-in line 1041. Plated layers 110c, 110a, 1101, and 110r may be disposed on the exposed portion of the circuit patterns 104c, the pad unit 104a, the reject marking portion 104r, and the plated lead-in line 1041. Each of the plated layers 110c, 110a, 1101, and 110r may be considered a circuit plated layer 110c, a pad plated layer 110a, a lead-in wire plated layer 1101, and a reject plated layer 110r. A second insulation layer may cover the second side 101b of the base substrate 102.

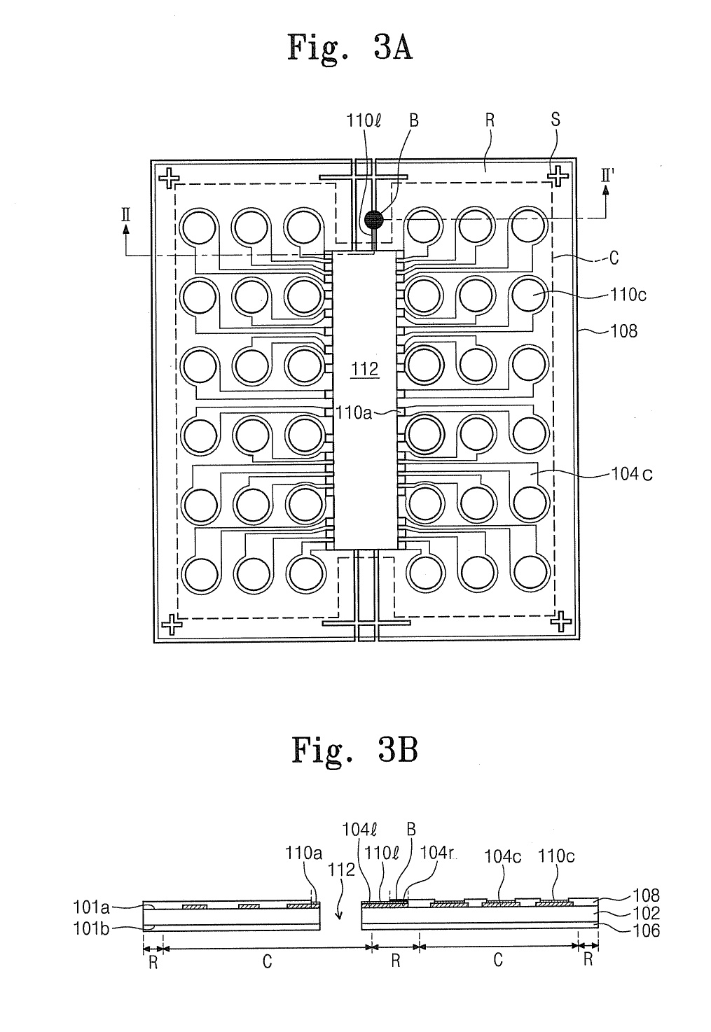

FIG. 3A is a plan view illustrating a reject mark on the unit substrate of FIG. 2A. FIG. 3B is a sectional view taken along the line II-IP of FIG. 3A.

Referring to FIGS. 2A through 2C and FIGS. 3A and 3B, after each unit substrate 100 of the strip-level printed circuit board 10 for a board-on-chip package is tested, if a defect is found on a unit substrate 100, a reject mark B is foamed on a reject marking portion 104r. The reject mark B may be formed using laser or an ink pen. If laser is used, a portion or entire of a reject plated layer 110r or a reject marking portion 104r therebelow may be melted or removed. When an ink pen is used, an ink may be applied on the reject plated layer 110r. FIGS. 3A and 3B illustrate a case when the reject mark B is formed using the ink pen.

Although example embodiments provide examples of devices that may be used to form a reject mark B, the invention is not limited thereto as there are devices other than an ink pen or a laser that may be used to generate the reject mark B. For example, various stamping mechanisms may be used to form the reject mark B. In addition, the reject mark B may be formed using a material other than ink.

The printed circuit board 10 for a board-on-chip package according to example embodiments may include a reject marking portion 104r in each unit substrate 100, so that the reject mark B may be marked on the reject marking portion 104r in a corresponding defective unit substrate 100. Accordingly, recognition errors of the reject mark B may be reduced. Additionally, accurately determining a defective substrate may prevent a normal substrate from being recognized as a defective substrate or reduce the number of occurrences of a normal substrate as being recognized as a defective substrate.

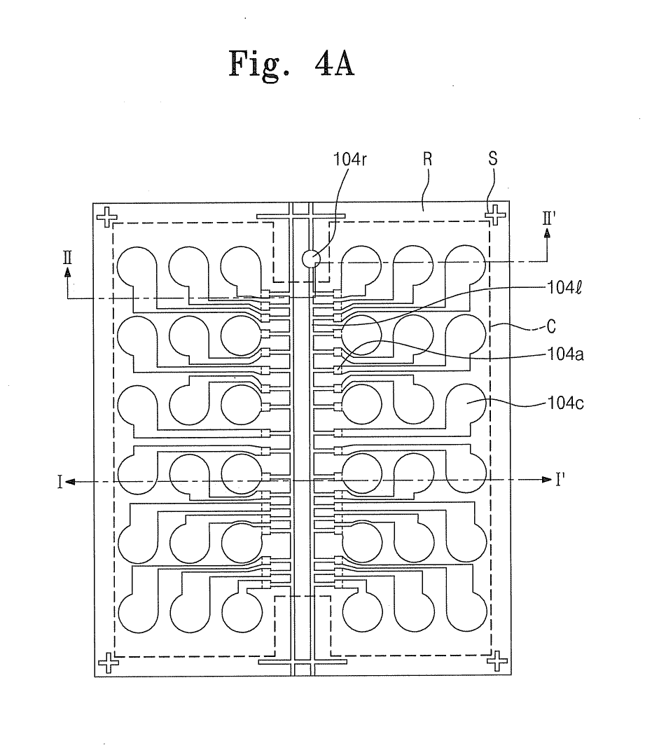

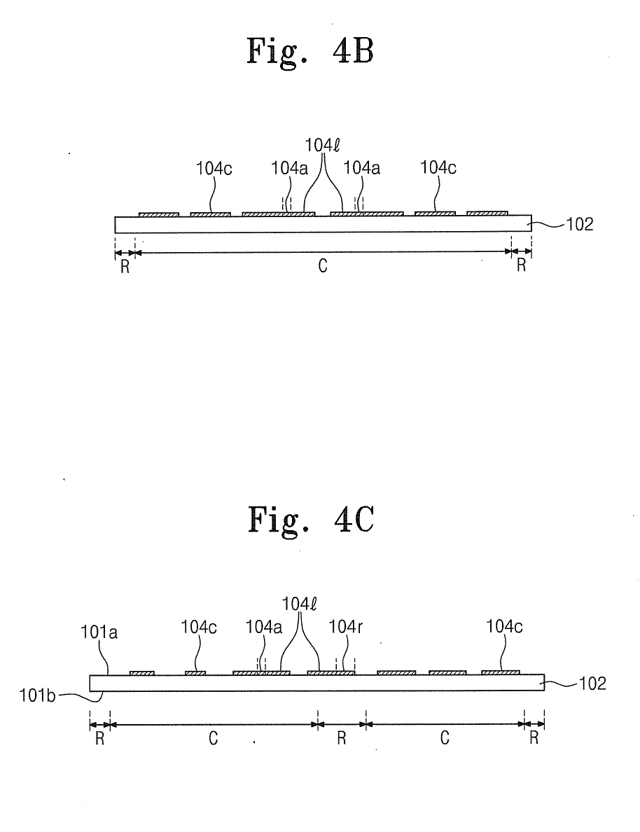

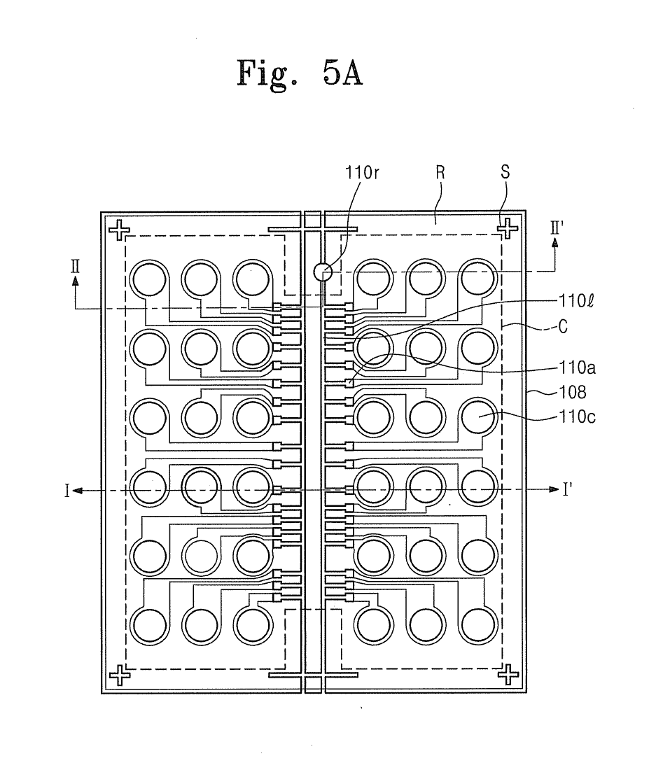

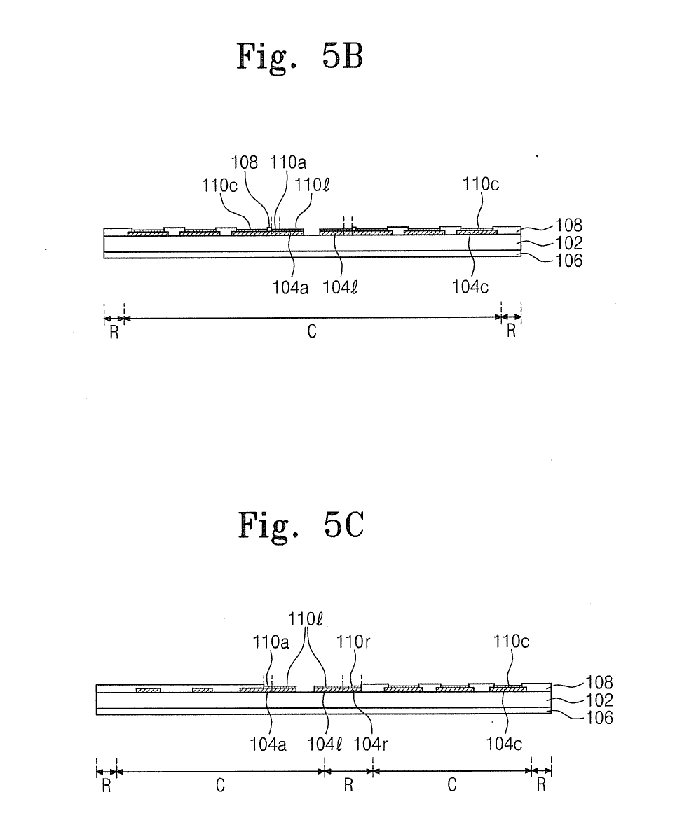

Next, a method of fabricating the printed circuit board 10 for a board-on-chip package will be described. A unit substrate 100 will be mainly described. FIGS. 4A and 5A are plan views illustrating processes of fabricating the unit substrate of FIG. 2A. FIGS. 4B and 5B are sectional views taken along the lines I-I′ of FIGS. 4A and 5A, respectively. FIGS. 4C and 5C are sectional views taken along the lines II-II′ of FIGS. 4A and 5A, respectively.

Referring to FIGS. 4A through 4C, a base substrate 102 having a first side 101a and a second side 101b facing the first side 101a and also a circuit region C and a peripheral region R is prepared. The base substrate 102 may be formed of insulation material. A circuit pattern 104c, a pad unit 104a, a plated lead-in line 1041, and a reject marking portion 104r may be faulted on the first side 101a of the base substrate 102. The circuit pattern 104c, the pad unit 104a, the plated lead-in line 1041, and the reject marking portion 104r may be formed by forming a copper layer on an entire surface of the first side 101a through an electroless plating method and then by etching the copper layer using a resist pattern as an etch mask. Accordingly, the circuit pattern 104c, the pad unit 104a, the plated lead-in line 1041, and the reject marking portion 104r may be formed simultaneously. Although not shown in the drawings, a conductive pattern may be formed on the second side 102b.

Referring to FIGS. 5A through 5C, a first insulation layer 108 may be formed on the first side 101a and then may be partially patterned to expose a portion of the circuit pattern 104c, the pad unit 104a, the plated lead-in line 1041, and the reject marking portion 104r. The exposed portion of the circuit pattern 104c may serve as a ball land layer, to which a bump is attached. A second insulation layer 106 may be formed on the second side 101b. Then, electricity may be applied to the exposed plated lead-in line 1041 to perform an electro plating process, so that plated layers 110c, 110a, 1101, and 110r are formed on the exposed portion of the circuit pattern 104c, the pad unit 104a, the plated lead-in line 1041, and the reject marking portion 104r. Each of the plated layers 110c, 110a, 1101, and 110r may be considered a circuit plated layer 110c, a pad plated layer 110a, a lead-in wire plated layer 1101, and a reject plated layer 110r. The plated layers 110c, 110a, 1101, and 110r may be formed of single/multilayer of Ni and/or Au. The plated layers 110c, 110a, 1101, and 110r may be formed through an electro plating process which may provide better characteristics than an electroless plating process in terms of reliability.

Referring to FIGS. 2A through 2C again, the lead-in plating layer 1011 at the center of the circuit region C, the plated lead-in lines 1041 therebelow, and the base substrate 102 therebelow are removed using a router bit to form an opening 112.

After the forming of the strip-level printed circuit board 10 including the unit substrate formed through the above processes, each unit substrate 100 is tested to determine whether there is a defect or not and then a reject mark B is marked on a reject marking portion 104r in a defective unit substrate 100 as shown in FIGS. 3A and 3B. The reject mark B is not marked on the reject marking portion 104r in a normal unit substrate 100.

Then, processes of forming a board-on-chip package including the unit substrate 100 formed through the above processes will be described.

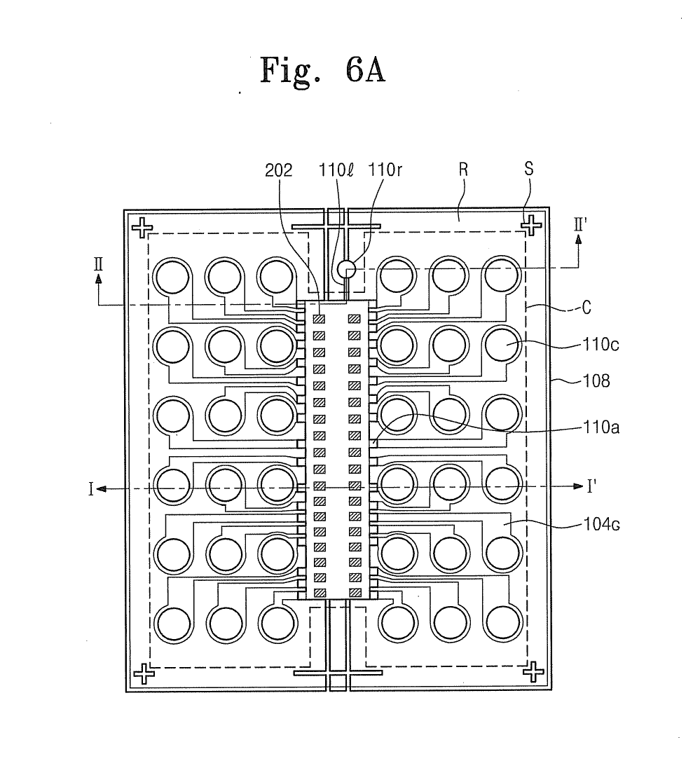

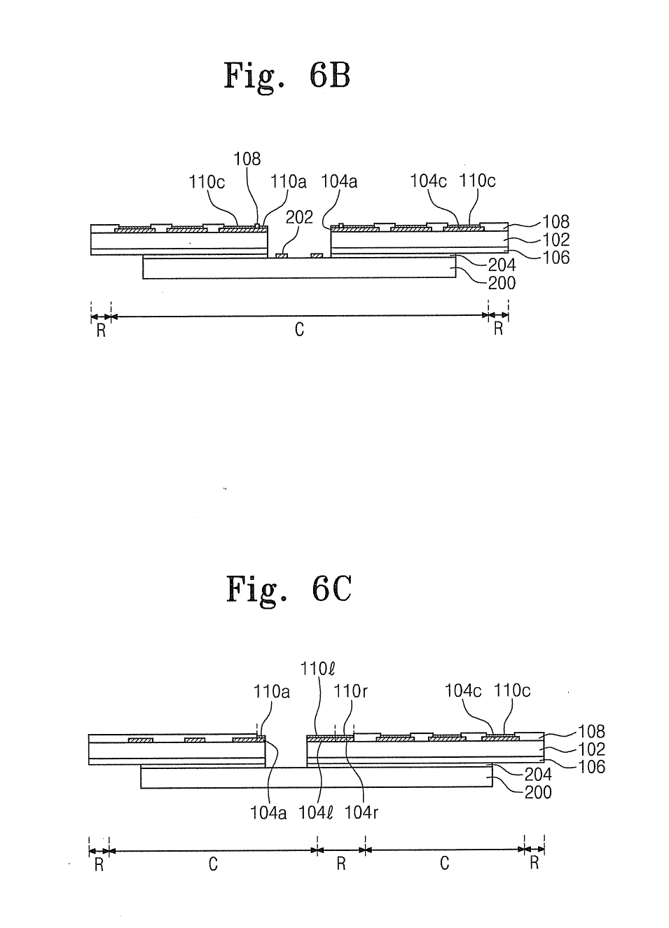

FIGS. 6A, 7A, and 8A are plan views sequentially illustrating processes of forming a board-on-chip package according to example embodiments. FIGS. 6B, 7B, and 8B are sectional views taken along the lines I-I′ of FIGS. 6A, 7A, and 8A. FIGS. 6C, 7C, and 8C are sectional views taken along the lines II-II′ of FIGS. 6A, 7A, and 8A.

Referring to FIGS. 6A through 6C, after a defect unit substrate is determined and a reject mark is selectively marked thereon, a semiconductor chip 200 is mounted on the second side 101b of the base substrate 102 while the reject mark is monitored using a monitoring camera for reject mark. The mounting of the semiconductor chip 200 may be performed using an adhesive material 204. A normal semiconductor chip 200 may be mounted on the normal unit substrate 100 with no reject mark B and a dummy semiconductor chip may be mounted on a defective unit substrate 100 with a reject mark B. The semiconductor chip 200 may be mounted to allow connection terminals 202 of the semiconductor chip 200 to be exposed to the opening 112 of the unit substrate 100.

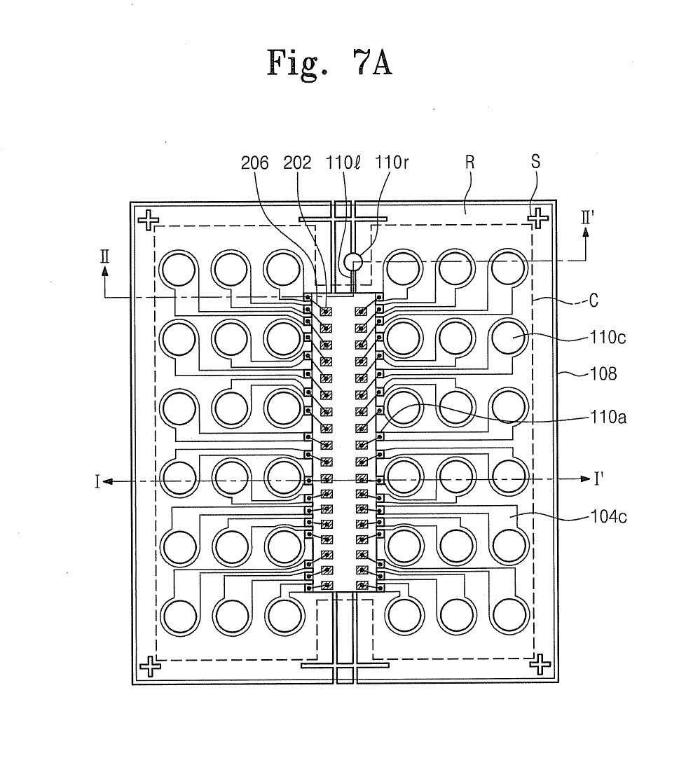

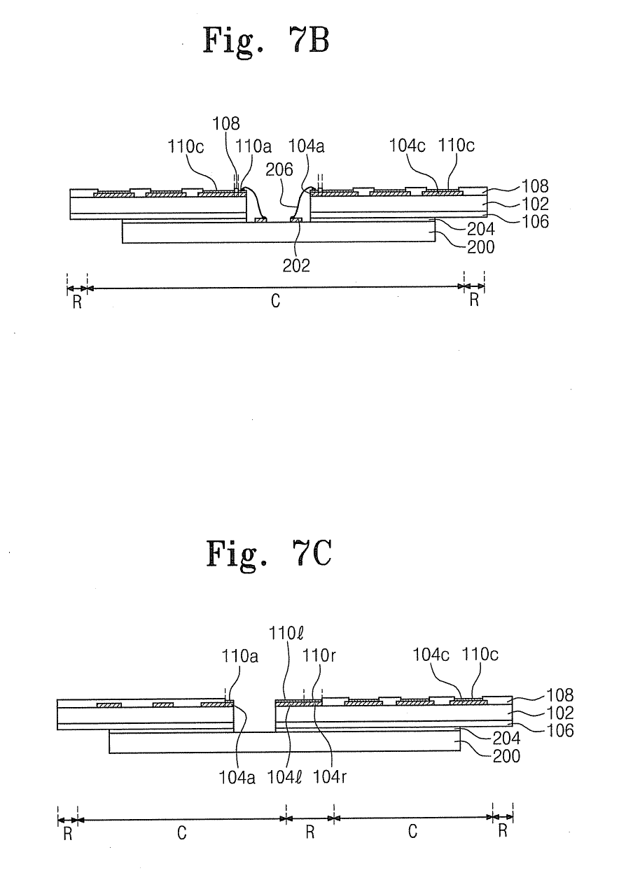

Referring to FIGS. 7A through 7C, while the reject mark is monitored using the monitoring camera for reject mark, a wire bonding process is performed. At this point, the wire bonding process is performed on a normal unit substrate 100 but is not performed on a defective unit substrate 100. The wire bonding process includes connecting a pad unit 104a of the normal unit substrate 100 with the connection terminal 204 of the normal semiconductor chip 200 through a wire 206.

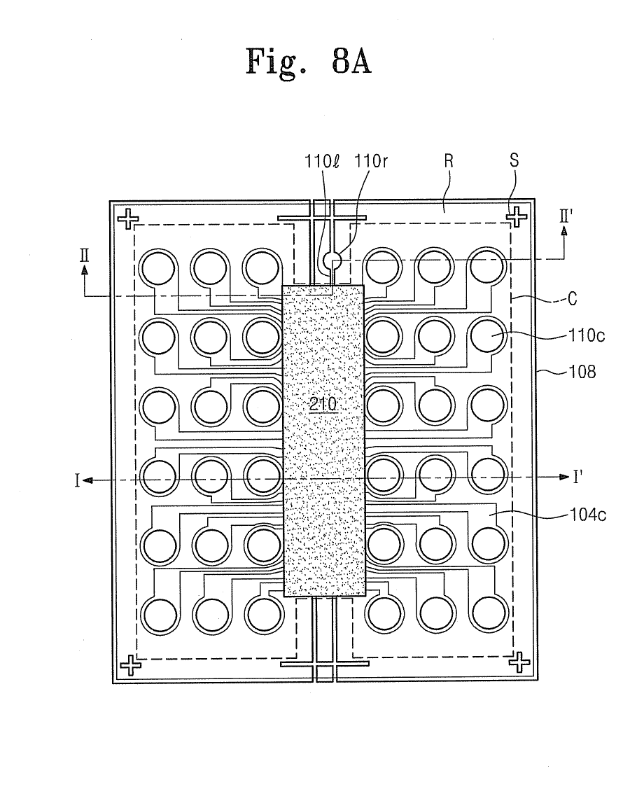

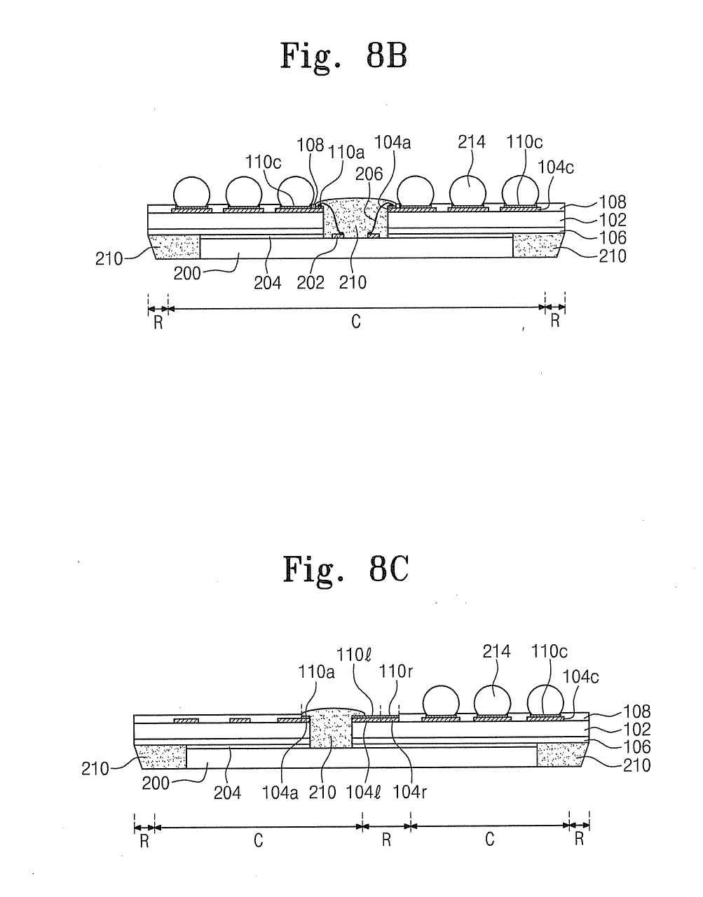

Referring to FIGS. 8A through 8C, a molding process is performed. The molding process may be performed in a mold frame and may fill the opening 112 with a molding compound 210, for example, epoxy, and may cover the side edge of the semiconductor chip 200 simultaneously. Moreover, a bump 214, for example, a solder ball, may be formed on the circuit plated layer 110c on the first side 101a. In example embodiments, a sorter process may be performed to separate each unit substrate 100 from the strip-level substrate 10 using a blade, so that a package process may be completed.

Thus, in relation to a board-on-chip package according to example embodiments and a method of fabricating the same, a reject marking portion may be equipped in each unit substrate so that a defective substrate may be easily determined. As a result, its reliability and yield may be improved.

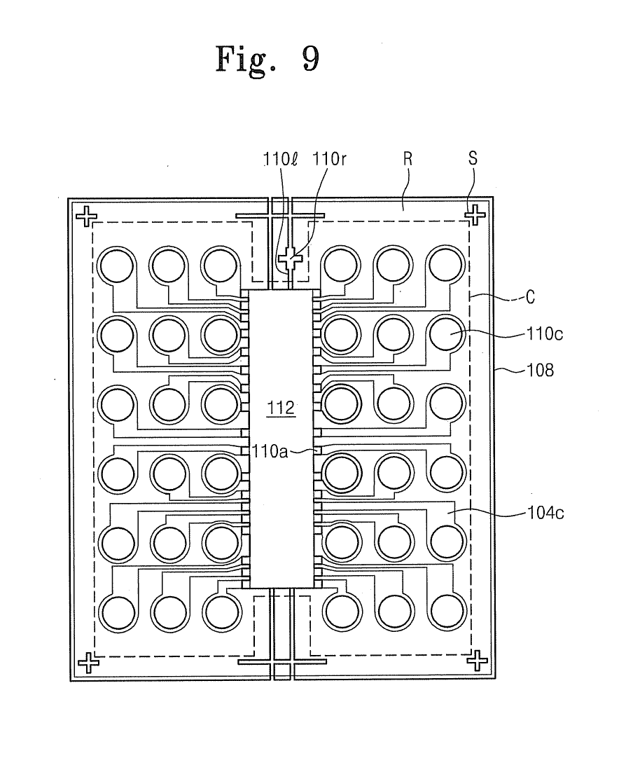

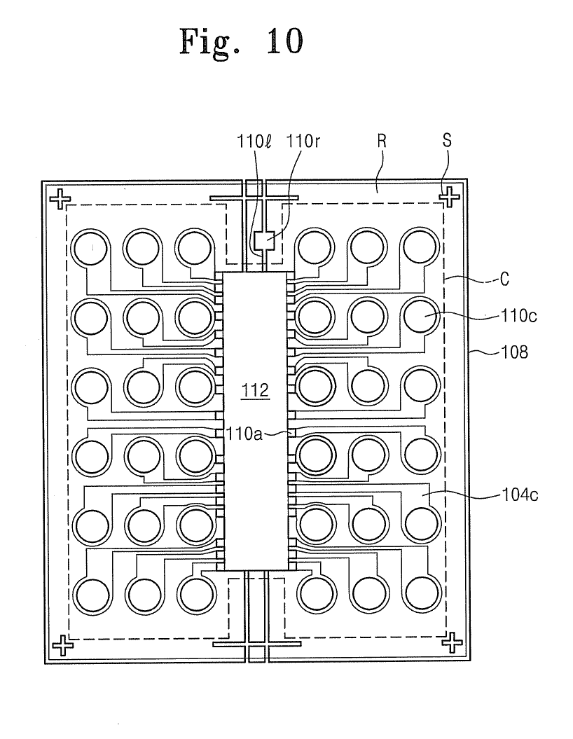

FIGS. 9 and 10 are plan views illustrating strip-level substrates for a board-on-chip package according to example embodiments.

Referring to FIGS. 9 and 10, a plane shape of the reject marking portion 104r may have a cross or rectangular shape unlike a circuit shape as shown in FIG. 2A. Other configurations are the same as those of FIG. 2A. A shape of the reject marking portion 104r is not limited thereto and may vary.

The semiconductor package techniques may be applied to various kinds of semiconductor devices and package modules including the same.

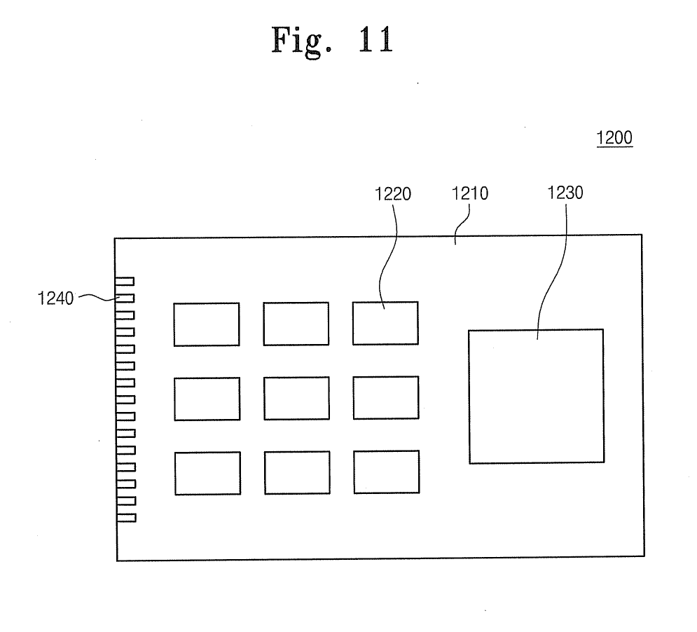

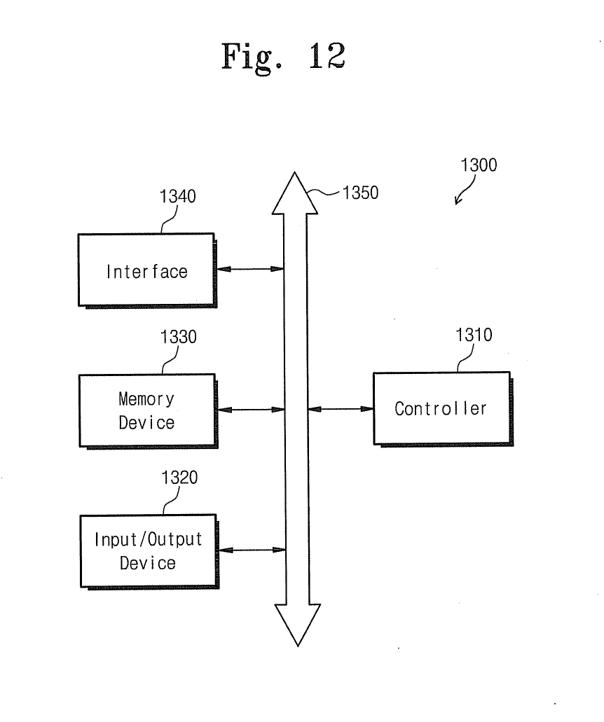

FIG. 11 is a view illustrating an example of a package module including a semiconductor package that the technique of example embodiments is applied. Referring to FIG. 11, the package module 1200 may include a semiconductor integrated circuit chip 1220 and a Quad Flat Package (QFP) applied semiconductor integrated circuit chip 1230. As the semiconductor devices 1220 and 1230 to which a semiconductor package technique of example embodiments is applied are mounted on a substrate 1210, the package module 1200 may be formed. The package module 1200 may be connected to an external electronic device through an external connection terminal 1240 at one side of the substrate 1210.

The above semiconductor package technique may be applied to an electronic system. FIG. 12 is a block diagram illustrating an example of an electronic device including a semiconductor package that the technique of example embodiments is applied. Referring to FIG. 12, the electronic system 1300 may include a controller 1310, an input/output device (or I/O) 1320, for example, a keypad, a keyboard, and a display, and a memory device 1330. The controller 1310, the input/output device 1320, and the memory device 1330 may be combined through a bus 1350. The bus 1350 is a path through which data may transfer. For example, the controller 1310 may include at least one micro processor, digital signal processor, micro controller, or other processors similar thereto. The controller 1310 and the memory device 1330 may include a semiconductor package according to example embodiments. The input/output device 1320 may include a keyboard, a keypad, or a display device. The memory device 1330 may store data. The memory device 1330 may store data and/or commands executed by the controller 1310. The memory device 1330 may include a volatile memory device and/or a nonvolatile memory device. Or, the memory device 1310 may be formed of a flash memory. For example, a flash memory to which the technique of example embodiments is applied may be mounted on an information processing system, for example, a mobile device or a desktop computer. This flash memory may include a semiconductor disk device (SSD). In this case, the electronic system 1300 may stably store a large amount of data in the flash memory system. The electronic system 1300 may further include an interface 1340 for transmitting or receiving data to or from a network. The interface 1340 may have a wire/wireless form. For example, the interface 1340 may include an antenna or a wire/wireless transceiver. Although not shown in the drawings, it is apparent to those skilled in the art that the electronic system 1300 may further include an application chipset, a camera image processor (CIS), and an input/output device.

The electronic system 1300 may be realized with a mobile system, a personal computer, an industrial computer, or a system performing various functions. For example the mobile system may be a personal digital assistant (PDA), a portable computer, a web tablet, a mobile phone, a wireless phone, a laptop computer, a memory card, a digital music system, or an information transmitting/receiving system. If the electronic system 1300 is a device for wireless communication, it may use a communication interface protocol of the third generation communication system, for example, code division multiple access (CDMA), global system for mobile communications (GSM), enhanced-time division multiple access (E-TDMA), wideband code division multiple access (W-CDMA), and CDMA1000.

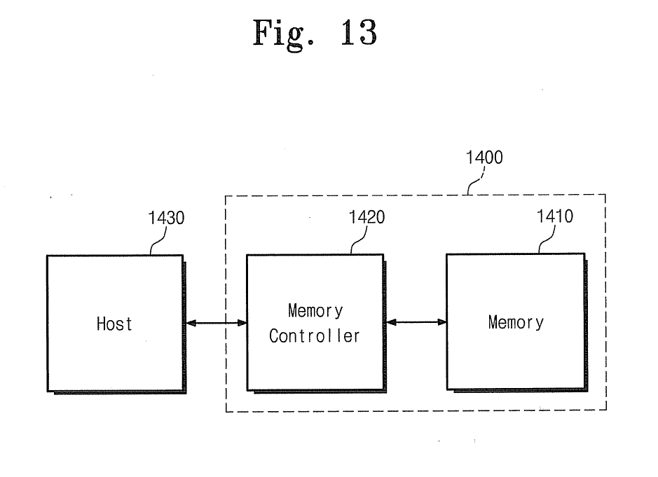

A semiconductor device to which the technique of example embodiments is applied may be provided with a form of a memory card. FIG. 13 is a block diagram illustrating a memory system with a semiconductor package that the technique of the example embodiments is applied. Referring to FIG. 13, the memory card 1400 may include a non-volatile memory device 1410 and a memory controller 1420. The non-volatile memory device 1410 and the memory controller 1420 may store data or read the stored data. The non-volatile memory device 1410 may include at least one of the non-volatile memory devices that the technique of example embodiments is applied. The memory controller 1420 may control the flash memory device 1410 to read stored data or store data in response to a read/write request from a host 1430.

A printed circuit board for a board-on-chip package according to example embodiments includes a reject marking portion in each unit substrate, thereby reducing recognition errors of a reject mark.

A printed circuit board for a board-on-chip package according to example embodiments may include a reject marking portion in each unit substrate, thereby improving its reliability since a defective substrate is easily determined.

A method of fabricating a board-on-chip package according to example embodiments may increase a yield rate by forming a reject unit in a unit substrate to reduce recognition errors and accurately determining a defective substrate to prevent a normal substrate from being recognized as a defective substrate or reduce the occurrence of a normal substrate from being recognized as a defective substrate.

The above-disclosed subject matter is to be considered illustrative and not restrictive, and the appended claims are intended to cover all such modifications, enhancements, and other embodiments, which fall within the true spirit and scope of the inventive concepts. Thus, to the maximum extent allowed by law, the scope of the inventive concepts is to be determined by the broadest permissible interpretation of the following claims and their equivalents, and shall not be restricted or limited by the foregoing detailed description.

1. A printed circuit board of a strip level for a board-on-chip package, comprising:
a plurality of unit substrates, each unit substrate including a reject marking portion identifying whether or not the unit substrate is defective.

2. The printed circuit board for a board-on-chip package of claim 1, wherein
the unit substrate includes a circuit region and a peripheral region at an edge of the circuit region, and
the reject marking portion is in the peripheral region.

3. The printed circuit board for a board-on-chip package of claim 1, wherein
the unit substrate includes a circuit pattern and a plated lead-in line connected to the circuit pattern, and
the reject marking portion is connected to the plated lead-in line.

4. The printed circuit board for a board-on-chip package of claim 1, wherein the reject marking portion has one of a circular, polygonal, and cross shape.

5. The printed circuit board for a board-on-chip package of claim 1, wherein the unit substrate has a first side to which a solder ball is attached and a second side on which a semiconductor chip is mounted, and the reject marking portion is on the first side.

6. The printed circuit board for a board-on-chip package of claim 1, wherein the unit substrate includes an opening region, and the reject marking portion is adjacent to the opening region.

7. A board-on-chip package comprising:
a unit substrate including a reject marking portion and an opening; and
a semiconductor chip mounted on one side of the unit substrate,
wherein the semiconductor chip is electrically connected to the unit substrate through the opening.

8-10. (canceled)

11. A unit substrate comprising:
a base substrate, the base substrate including a circuit region and a peripheral region; and
a reject marking portion in the peripheral region, the reject marking portion indicating whether the unit substrate is defective.

12. The unit substrate of claim 11, wherein the reject marking portion is one of circular, cross, and polygon shaped.

13. The unit substrate of claim 11, further comprising:
a circuit pattern in the circuit region, the circuit pattern having a plated layer thereon; and
a lead-in line extending from the circuit region to the reject marking portion.

14. The unit substrate of claim 13, further comprising:
a plurality of solder balls on the plated layer of the circuit pattern.

15. The unit substrate of claim 13, further comprising:
a pad layer arranged near an opening in the base substrate, the pad layer being electrically connected to the circuit pattern.

16. A board-on-chip package comprising:
the unit substrate of claim 15; and
a semiconductor chip connected to the unit substrate through the opening.

17. The board-on-chip package of claim 16, further comprising:
a plurality of wires, the plurality of wires electrically connecting the semiconductor chip to the unit substrate.

18. The board-on-chip package of claim 17, wherein the wires connect to connection terminals of the semiconductor chip and the pad layer of the unit substrate.

19. The board-on-chip package of claim 18, wherein the semiconductor chip is attached to a bottom surface of the unit substrate by an adhesive and the pad layer of the substrate is on an upper surface of the unit substrate.

20. The board-on-chip package of claim 19, wherein the semiconductor chip is a dummy semiconductor chip and the reject marking portion is marked indicating the unit substrate is defective.

21. The board-on-chip package of claim 19, further comprising:
an encapsulant in the opening and extending from top surface of the semiconductor chip to above a top surface of the unit substrate to enclose the wires.
